(19) United States
(12) Patent Application Publication
(10) Pub. No.: US 2005/0204221 A1
(43) Pub. Date: Sep. 15, 2005

(54) Apparatus and method for exchanging non-JTAG signals with a core processor during selected JTAG modes

(76) Inventor: Gary L. Swoboda, Sugar Land, TX (US)

Correspondence Address: TEXAS INSTRUMENTS INCORPORATED, P O BOX 655474, M/S 3999, DALLAS, TX, 75265, US

(21) Appl. No.: 11/080,698

(22) Filed: Mar. 15, 2005

Related U.S. Application Data
(60) Provisional application No. 60/553,081, filed on Mar. 15, 2004.

(51) Int. Cl. G01R 31/28

(52) U.S. Cl. 714/724

(57) ABSTRACT

In selected JTAG states, the data input and output terminals are not used for several clock cycles. By recognizing the appropriate selected JTAG states and providing circuits to permit the transfer of non-JTAG data during these selected states, a more efficient use of the terminals which provide an interface between the emulation unit and the JTAG interface logic can be achieved.

This application claims priority under 35 USC §119(e) (1) of Provisional Application No. 60/553,081 (TI-38117PS) filed Mar. 15, 2004.

### BACKGROUND OF THE INVENTION

1. Field of the Invention

This invention relates generally to data processing systems and, more particularly, to the testing of integrated circuits.

2. Background of the Invention

As the number of components and the complexity of integrated circuits have increased, the importance of testing these integrated circuits has increased. The importance of testing has become so great that many components in a circuit are now dedicated to the testing (and program debug) involving these circuits. Concurrently, integrated circuits have continually been reduced in size. One of the most important consequences of this size reduction, along with the increased complexity and functionality of the integrated circuit, has been the problem of providing the necessary electrical connections between the integrated circuit and the components not fabricated in the circuit. The testing and program debug associated with the testing of the integrated circuit requires additional terminals. For example, the Joint Test Action Group (JTAG) boundary scan interface procedure (IEEE standard number 1149) requires five terminals to accomplish the specified test procedure.

Referring to FIG. 1, the signal paths needed to implement the JTAG procedures are illustrated. An emulation unit 5 exchanges signals with an integrated circuit 10 and specifically with interface logic 11. The interface logic 11 exchanges signals with the processor core 15, the processing core 15 being the unit under test. The signals that are exchanged between the emulation unit 5 and the interface logic 11 include the TDI signals, the TCK signals, the TMS signals, the TRST signals, and the TDO signals.

Specifically, the TDI (test data in) signals are signals that are applied to interface logic 11 from the emulation unit 5 that are entered in the JTAG registers. The TDO (test data out) signals are serial output signals from JTAG registers to the equipment controlling the test. The TCK (test clock) signals are signals that control the timing of the interface independently from any system clock. The TMS (test mode select) signals are the signals that control the transitions of the states of the interface logic 11. The TRST signals are the signals that initialize and disable the interface logic.

In the implementation of the JTAG procedures, TRI signals are serially scanned into the processing core. In this manner, the initial state processing core 15 can be established. The core processor then executes an operation involving at least one system clock cycle. The TDO signals are then serially scanned out allowing the test apparatus to identify a subsequent (i.e., as compared to the initial) state. In some modes of operation, TDI signals can be scanned in while TDO signals are being scanned out.

The foregoing discussion provides only enough detail to understand the present invention. As will be clear to those skilled in the art, the testing of an integrated circuit is much more complex than has been described.

A need has therefore been felt for apparatus and an associated method having the feature of being able to exchange of non-procedure signals between an external component and an integrated circuit during the operation of a JTAG procedure. It will be yet another feature of the apparatus and associated method to exchange non-procedure JTAG signals between an external component and an integrated circuit in selected states during a JTAG procedure. It would be a more particular feature of the present invention to exchange on-procedure signals between and external component and an integrated circuit during JTAG procedure in a data-in state mode, a data-out state and an idle state.

### SUMMARY OF THE INVENTION

The foregoing and other features are accomplished, according the present invention, by, during a JTAG procedure, identifying JTAG states when the data-in and data-out terminals are not being used. These terminals are then used to exchange non-JTAG signals between an external component and an integrated circuit during a period of inactivity. The states that can be inactive and therefore permit the exchange of non-JTAG signals are the test idle state, the pause DR state, and the pause IR state. Once these states are entered, these states are maintained by a selected TMS signal.

Other features and advantages of present invention will be more clearly understood upon reading of the following description and the accompanying drawings and the claims.

### BRIEF DESCRIPTION OF THE DRAWINGS

FIG. 1 is a block diagram of a JTAG test configuration in which signals are exchanged with a core processor according to the prior art.

FIG. 2 is a state diagram for the interface logic controlling the exchange of data between the emulation unit and the processor core.

FIG. 3 is a block diagram illustrating the exchange of non-JTAG data though JTAG terminals according to the present invention.

### DESCRIPTION OF THE PREFERRED EMBODIMENT

### 1. Detailed Description of the Figures

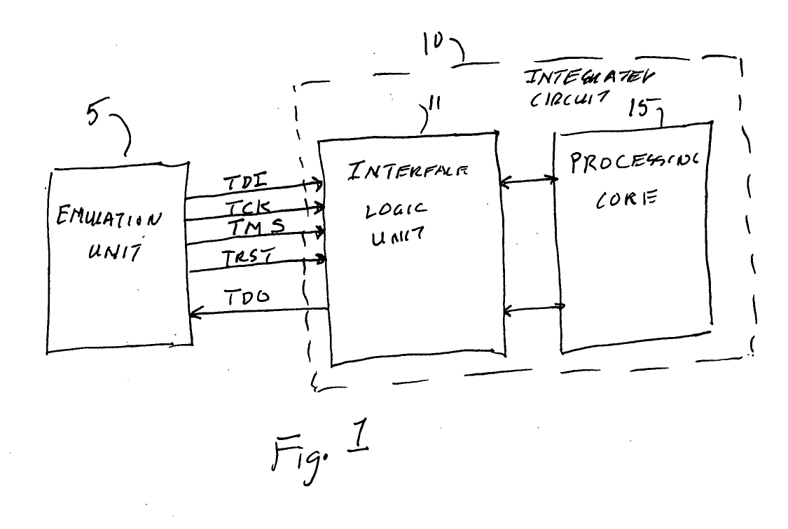

FIG. 1 has been described with respect to the prior art.

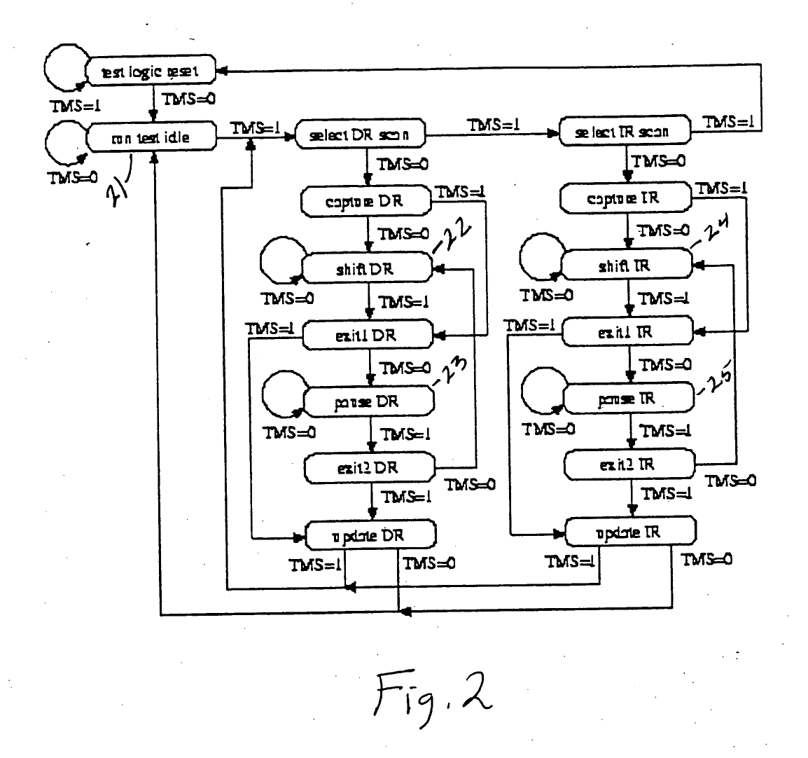

Referring to FIG. 2, the JTAG state diagram for the interface logic 11 is shown. This state diagram is widely familiar to those skilled in the art and only those features necessary in understanding the present invention will be discussed. Every state has two exit paths. These exit paths are determined by the logic value of the TMS signal. Five of the states are parking states, i.e. one logic signal (TMS=0) causes the state to remain unchanged. In FIG. 2, the parking states are RUN TEST IDLE state 21, SHIFT DR state 22, PAUSE DR state 23, SHIFT IR state 24, and PAUSE DR state 25. The IR designation refers to the transfer of data from the interface logic 11 and the DR state refers to transfer of data to the interface logic 11. As will be clear, in the SHIFT DR state 22 and the SHIFT IR 24 states, while the state does not change, data is being transferred over the associated interface terminal. Thus, the corresponding terminals are unavailable. However, during the RUN TEST IDLE state 21, the PAUSE DR state 23 and the PAUSE IR state 25, the state of the interface logic does not change and data is not transferred across the terminals. Therefore, these three JTAG states are available for the transfer of non-JTAG data across the JTAG terminals.

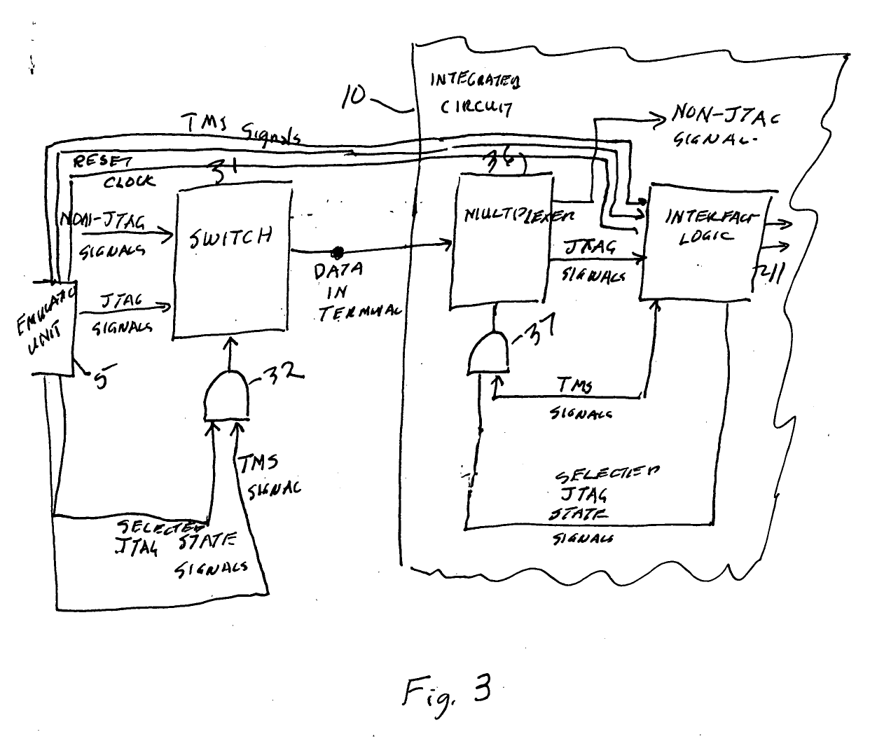

Referring to FIG. 3, apparatus for implementing the transfer of non-JTAG data during selected JTAG states is illustrated. The JTAG signals from the emulation unit 5 are applied to one input terminal of switch 31. A second input terminal of switch 31 has non-JTAG signals applied thereto. A logic AND gate 32 received selected JTAG state signals on a first input terminal and the TMS signals on a second input terminal. The output terminal of logic AND ate 32 applies a control signal to switch 32. the output terminal of switch 31 is coupled through the data input terminal of the JTAG interface terminals to an inp9ut terminal of multiplexer 36. One output terminal of multiplexer 36 is applied to the interface logic 11 of integrated circuit 10. A second output terminal of multiplexer 36 is coupled to non-JTAG components. An output terminal of logic AND gate 37 applies a control signal to multiplexer 36. TMS signals and selected JTAG state signals are applied to first and second input terminals of logic AND gate 37. A data out terminal has apparatus similar to that described with respect to the data in interface terminal associated therewith, the major difference being to accommodate data flow from the integrated circuit. The TMS signals, the TCK signals and the TRST signals are applied from the emulation unit 5 to the interface logic in the usual manner.

### 2. Operation of the Preferred Embodiment

The present invention can e understood in the following manner. When a JTAG cycling state (i.e., a state which is repeated updated, but without data transfer) is present, non-JTAG data can be transferred through the terminal(s) that would normally transfer data from and emulation unit to the JTAG interface logic unit. When the terminal is available for non-JTAG transfer, apparatus is activated which permits non-JTAG to be transferred. In this manner, the data-transferring JTAG terminals can be used to transfer non-JTAG data during the periods of JTAG non-use. The limited number of terminals can, in this manner be used more effectively.

The foregoing discussion illustrates the invention. However, as will be clear to one skilled in the art, more elaborate algorithms and apparatus can increase the availability of the data transfer terminals.

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

1. A method for transferring data from external components to an integrated circuit over terminals used to exchange JTAG data signals, the method comprising:
identifying a selected interface logic JTAG state,
based on the selected state, applying a non-JTAG data stream to an interface terminal associated with the selected state; and
based on the selected state, distributing the non-JTAG data stream to predetermined components.

2. The method as recited in claim 1 wherein the selected JTAG state is selected from the group consisting of the PAUSE IR state, the PAUSE DR state, and the RUN TEST IDLE state.

3. The method as recited in claim 2 further comprising using the JTAG TMS signals along with the JTAG state to determine the interface terminal.

4. The method as recited in claim 3 wherein the non-JTAG signals are applied to at least one of the terminals in the group consisting of the JTAG data in terminal and the JTAG data out terminal.

5. Apparatus for exchanging signals between external components including a JTAG test unit and integrated circuit components including a JTAG interface logic unit, the apparatus comprising:
an interface terminal for transferring data signals from external components to integrated circuit components;
a switch, the switch responsive to JTAG state and control signals for selecting signal source to be applied to the interface terminal; and
a multiplexer, the multiplexer responsive to JTAG state and control signals for selecting a destination for signals from the single source.

6. The apparatus as recited in claim 5 wherein the JTAG state signals are selected from a group consisting of signals identifying the PAUSE DR state, the PAUSE IR state, and the RUN TEST IDLE state.

7. The apparatus as recited in claim 5 wherein the control signals are JTAG TMS signals.

8. The apparatus as recited in claim 5 wherein data is transferred from external components including the JTAG test unit to integrated circuit components including interface logic unit.

9. The apparatus as recited in claim 5 wherein data is transferred from integrated circuit components including the interface logic unit to external components including the JTAG test unit.
